(19) United States
(12) Patent Application Publication
(10) Pub. No.: US 2024/0313520 A1
(43) Pub. Date: Sep. 19, 2024

(54) JOINT OF MgB2 SUPERCONDUCTING WIRES

(71) Applicants: NV Bekaert SA, Zwevegem (BE); EPOCH WIRES LIMITED, Cambridge (GB)

(72) Inventors: Serdar ATAMERT, Cambridge (GB); Mehmet KUTUKCU, Cambridge (GB); Chris D'HULST, Oeselgem (BE); Jan MESTDAGH, Harelbeke (BE)

(73) Assignees: NV Bekaert SA, Zwevegem (BE); EPOCH WIRES LIMITED, Cambridge (GB)

(21) Appl. No.: 18/576,526

(22) PCT Filed: Jul. 4, 2022
(86) PCT No.: PCT/EP2022/068364

§ 371 Date: Jan. 4, 2024

(30) Foreign Application Priority Data
Jul. 6, 2021 (EP) 21250004.5

(51) Int. Cl. H02G 15/18; H02G 1/14

(52) U.S. Cl. CPC H02G 15/18; H02G 1/14

(57) ABSTRACT

A joint of superconducting wires having at least two superconducting wires, each with a sheath and with a core of reacted superconducting MgB₂. At least one first superconducting wire has a first flattened end and at least one second superconducting wire has a second flattened end. The joint further has a tubular metal connector having a centre filled with MgB₂ material. The first flattened end of the first superconducting wire is inserted at one side of the connector until it is in contact with the MgB₂ material, the second flattened end of the second superconducting wire is inserted at the other side of the connector until it is in contact with the MgB₂ material, the connector is pressed at both sides to fix the superconducting wires, and the centre of the connector is pressed to compact the MgB₂ material.

### TECHNICAL FIELD

The invention relates to a joint of superconducting wires with magnesium diboride (MgB₂) as superconducting core and to a method of making such a joint.

### BACKGROUND ART

Magnesium diboride is an inorganic compound with the formula MgB₂. Magnesium diboride's superconducting properties were discovered in 2001. MgB₂ becomes superconducting at 39 K (−234° C.), which is the highest amongst conventional superconductors. This allows the functioning as superconductor without the need for using liquid helium.

In order to keep its superconducting properties, the very low electrical resistance must also be present at joints, where two ends of superconducting wire are joined. Having regard to the very fragile properties of the superconducting material, this is not a straightforward task.

The prior art has disclosed various alternatives for realizing a superconducting joint.

US-A1-2009/0105079 discloses a superconductive connection for two end pieces of superconductors using a sheath or bushing where MgB₂ as superconductive contacting material is inserted. The superconductors are multi-wire superconductors. The connection shows a region inside the sheath or bushing where the superconducting wires overlap, i.e. the cross-section shows the presence of superconducting wires coming from the two end pieces of superconductors.

KR-A-10-2020-0103369 discloses a superconductive connection for two end pieces of superconductors of the single wire type. The superconductor of the single wire type is a round wire with a MgB₂ superconducting core surrounded by a stabilization layer and a metal sheath. In order to realize the connection, the end pieces of the superconducting wires are flattened to a very large degree to increase the bonding area. The width to thickness ratio ranges from 3 to 100. The stabilization layer and metal sheath are removed at one side of the flattened ends so that the superconducting cores become open at one side. The open sides of the superconducting cores are then brought in contact with each other. The contacting ends are introduced in a bonding container where sintered powder of Mg and B or of MgB₂ is introduced and put under pressure.

### DISCLOSURE OF INVENTION

It is an object of the invention to provide for an alternative superconductive joint.

It is another object of the invention to simplify superconductive joints.

It is a specific object of the invention to allow jointing of superconductive wires with already reacted MgB₂.

According to the first aspect of the invention there is provided a joint of superconducting wires. The joint comprises at least two superconducting wires each with a sheath and with a MgB₂ superconducting core inside the sheath. At least one first superconducting wire has a first flattened end and at least one second superconducting wire has a second flattened end. The joint further comprises a tubular metal connector. The connector has a centre being filled with magnesium or boron or MgB₂ material. The first flattened end of first superconducting wire is inserted at one side of the connector until it is in contact with the magnesium or boron or MgB₂ material. The second flattened end of the second superconducting wire is inserted at the other side of the connector until it is also in contact with the magnesium or boron or MgB₂ material. The connector is pressed at both sides to fix the first superconducting wire and the second superconducting wire. The centre of the connector is pressed to compact the magnesium or boron or MgB₂ material.

In comparison with the prior art, this invention joint does not need the superconducting wires to have an overlap. In addition, there is no need to remove the sheath of the superconducting wires.

The first flattened end and the second flattened end have a width-to-thickness ratio in order to get rid of the cavities and to provide a stable pressed wire that is no longer deformed during pressing of the connector. Preferably these flattened ends have a width to thickness ratio ranging from 1.1 to 10.0, preferably from 1.1 to 5.0, e.g. from 1.25 to 2.5, preferably from 1.50 to 2.0.

Since the first superconducting wire and the second superconducting wire comprise a core of reacted superconducting MgB₂ they also comprise voids. The reason is that the volume of reacted MgB₂ is roughly 25% less than the original Mg powders and B powders. The ends of the superconducting wires are pressed to such a degree that the number and volume of voids decrease. Later pressing of these already pressed ends of superconducting wires will no longer lead to large cracks which prevent electrical current.

The tubular metal connector preferably comprises low carbon steel.

The tubular metal connector may also comprise titanium.

The tubular metal connector may have a titanium barrier radially inside and a low carbon steel radially outside.

The tubular metal connector may preferably be made of low carbon steel only.

According to a second aspect of the invention there is provided a method of joining at least two superconducting wires having a superconducting core of reacted MgB₂. This method comprises the following steps:
a) providing at least one first superconducting wire and at least one second superconducting wire, the first superconducting wire having a first end and the second superconducting wire having a second end;
b) flattening the first end of the first superconducting wire and flattening the second end of the second superconducting wire;
c) providing a tubular metal connector having a length Lₜₒₜ and having a centre;
d) filling the centre of said connector with unreacted Mg powder and B powder;
e) flattening the connector in case the connector has an original circular cross-section;
f) inserting the first end of the first superconductor at one side in the connector over a length L₁ until contact with the Mg powder and B powder;
g) inserting the second end of the second superconductor at the other side in the connector over a length L₂ until contact with the Mg powder and B powder;
h) pressing the connector at both sides to fix the first superconductor wire and the second superconductor wire in the connector;
i) pressing the centre of the connector over a length L_{center} to compact the Mg powder and B powder, wherein the lengths Lₜₒₜ, L₁, L₂ and L_{center} matching following equation:

$${L}_{tot} = {L}_{1} + {L}_{2} + 2 \times {L}_{cr} + {L}_{center}$$

where L_{cr} is a critical distance between, on the one hand, the first flattened end and the second flattened end, and, on the other hand, the pressed length L_{center} of the centre of the connector needed to avoid that the superconducting wires are pressed together with the pressing of the centre.

In order to create superconductivity in the centre of the tubular metal connector and to restore the superconductivity in the flattened ends, the tubular metal connector and the flattened ends are subjected to a heat treatment.

This heat treatment preferably comprises two phases:
1) a first phase of heating in a range of 800° C. to 1000° C. during 20 minutes to 40 minutes; immediately followed by
2) a second phase of heating in a range of 550° C. to 750° C. during 45 minutes to 75 minutes.

Preferably the flattening of the ends of the superconducting wires are done to a degree where the width to thickness ratios of these ends range from 1.10 to 10.0, preferably from 1.10 to 5.0, most preferably from 1.50 to 2.5, e.g. from 1.50 to 2.0.

Preferable values of the critical distance L_{cr} range from 0.6 mm to 5.0 mm, preferably from 0.8 mm to 2.0 mm, e.g. from 0.8 mm to 1.2 mm.

### BRIEF DESCRIPTION OF FIGURES IN THE DRAWINGS

FIG. 1 is a schematic presentation of a preparation of a joint according to the invention.

FIG. 2 shows a joint according to the invention.

### MODE(S) FOR CARRYING OUT THE INVENTION

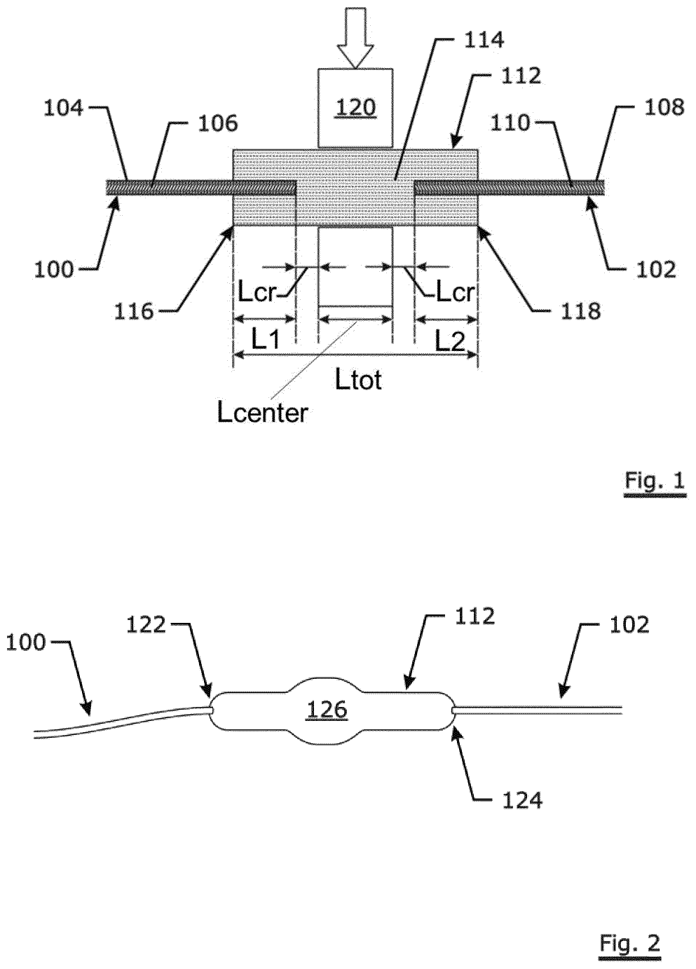

Referring to FIG. 1 the subsequent steps or joining a first superconducting wire 100 and a second superconducting wire 102 will be described. The numerical values are given by way of non-limiting example.

The first superconducting wire 100 has a sheath 104 of low carbon steel and a core 106 of reacted MgB₂.

The second superconducting wire 102 has a sheath 108 with a barrier layer of titanium and an outer layer of low carbon steel and a core 110 of reacted MgB₂.

A tubular metal connector 112 is provided and contains unreacted boron powder and magnesium powder. The boron powder is preferably a nano boron powder and the magnesium powder is preferably a spherical magnesium powder. By way of example, the external diameter of the tubular metal connector 112 is 5.6 mm to 6.0 mm and the metal tubular connector 112 is about 22 mm long.

The first end 116 and the second end 118 of the metal tubular connector 112 are first deburred.

Then, the first end 116 of the tubular metal connector 112 and the second end 118 of the tubular metal connector are immersed in a diluted HCl solution for a couple of seconds and thereafter dried under vacuum.

Both the first and 116 and the second end 118 are polished followed by alcohol washing and vacuum drying.

A hole of 1.25 mm is drilled in both the first end 116 and the second end 118 to match the dimensions of the first and the second superconducting wires 100 and 102. The length of the hole is L₁ at the sided of the first end 116 and L₂ at the side of the second end 118. Both L₁ and L₂ can be about 6.5 mm.

After drilling, the tubular metal connector 112 is flattened over its whole length Lₜₒₜ.

The first superconducting wire 100 and the second superconducting wire are flattened over a length that is greater than the drilling lengths L₁ and L₂.

The thus flattened ends of the first and second superconducting wire 100 and 102 are ground with an angle in order to increase the surface area. This grinding operation is again followed by alcohol washing and vacuum drying. Thereafter, the flattened ends of the first and second superconducting wires 100 and 102 dipped in a diluted solution of HCl, followed by washing in alcohol and drying in vacuum.

The flattened ends of the first and second superconducting wires 100 and 102 are inserted in the tubular metal connector 112 until they have contact with the boron and magnesium powder in the centre.

Pressure is exercised at both ends 116 and 118 of the tubular metal connector 112 in order to fix the superconducting wires 100 and 102 and to seal the ends 116 and 118.

The centre part of the tubular metal connector 112 is pressed over a length L_{center} by means of a hydraulic press 120. The length L_{center} before flattening is for example 6.35 mm.

A critical length L_{cr} of 1.0 mm remains at both sides between the flattened centre part of the tubular metal connector 112 and the drilled holes.

Finally, a heat treatment is applied to the assembly of the first and second superconducting wires 100, 102 and the tubular metal connector 112 with the Mg and B powder 114.

As mentioned, the heat treatment comprises two phases.

During the first phase the assembly is heated at 900° C. during 30 minutes. In this first phase, the following reaction takes place:

2MgB₂→Mg+MgB₄

During the second phase immediately following the first phase, the assembly is kept at a temperature of 650° C. during 60 minutes. During this second phase, the following reaction takes place:

Mg+MgB₄→2MgB₂

This double phase heat treatment not only create superconductivity in the centre of the tubular metal connector 112 but also restores the superconductivity in the flattened ends of the first and second superconducting wires 100 and 102.

FIG. 2 gives a schematical representation of a realized joint. More particularly, FIG. 2 shows the pressed ends 122 and 124 of the tubular metal connector 112 and the flattened central part 126. Typical dimensions in the finalized joint, i.e. after the flattening operations, are a total length Lₜₒₜ of 23.8 mm, a length L_{center} of the flattened central part of 7.25 mm, a length of insertion of first superconducting wire of 7.9 mm and a length of insertion of second superconducting wire of 8.7 mm.

### LIST OF REFERENCE NUMBERS

100 first superconducting wire
102 second superconducting wire
104 sheath of first superconducting wire
106 reacted MgB₂ inside first superconducting wire
108 sheath of second superconducting wire
110 reacted MgB₂ inside second superconducting wire
112 tubular metal connector
114 unreacted Mg powder and B powder
116 first end of tubular metal connector
118 second end of tubular metal connector
120 pressing tool
122 first pressed end of tubular metal connector
124 second pressed end of tubular metal connector
126 central pressed part of tubular metal connector

### LIST OF ABBREVIATIONS IN FIGURES

L₁ length of insertion of first superconducting wire
L₂ length of insertion of second superconducting wire
Lₜₒₜ length of the tubular metal connector
L_{cr} critical length
L_{center} length of pressure zone in central part of tubular metal connector

1. A joint of superconducting wires,
said joint comprising at least two superconducting wires each with a sheath and with a core of reacted superconducting MgB₂,
at least one first superconducting wire having a first flattened end and at least one second superconducting wire having a second flattened end,
said joint further comprising a tubular metal connector,
said connector having a centre being filled with magnesium or boron or MgB₂ material,
said first flattened end of said at least one first superconducting wire being inserted at one side of said connector until it is in contact with said magnesium or boron or MgB₂ material,
said second flattened end of said at least one second superconducting wire being inserted at the other side of said connector until it is in contact with said magnesium or boron or MgB₂ material,
said connector being pressed at both sides to fix said at least one first superconducting wire and said at least one second superconducting wire,
said centre of said connector being pressed to compact said magnesium or boron or MgB₂ material.

2. The joint according to claim 1,
wherein said first flattened end and said second flattened end have a width to thickness ratio ranging from 1.1 to 10, preferably from 1.1 to 5.0.

3. The joint according to claim 1,
wherein said tubular metal connector comprises low carbon steel.

4. The joint according to claim 1,
wherein said tubular metal connector comprises titanium.

5. (canceled)

6. A method of joining at least two superconducting wires having a superconducting core of reacted MgB₂, said method comprising the following steps:
a. providing at least one first superconducting wire and at least one second superconducting wire,
said at least one first superconducting wire having a first end and
said at least one second superconducting wire having a second end;
b. flattening said first end of said first superconducting wire and flattening said second end of said second superconducting wire;
c. providing a tubular metal connector having a length Ltot and having a centre;
d. filling said centre of said connector with unreacted Mg powder and B powder;
e. flattening said connector in case said connector has an original circular cross-section;
f. inserting said first end of said least one first superconductor at one side in said connector over a length L1 until contact with said Mg powder and B powder;
g. inserting said second end of said at least one second superconductor at the other side in said connector over a length L2 until contact with said Mg powder and B powder;
h. pressing said connector at both sides to fix said at least one first superconductor wire and said at least one second superconductor wire in said connector;
i. pressing said centre of said connector over a length Lcenter to compact said Mg and B powder, wherein said lengths Ltot, L1, L2 and Lcenter matching following equation:
$$Ltot = L 1 + L 2 + 2 \times Lcr + Lcenter$$
where Lcr is a critical distance between, on the one hand, the first flattened end and the second flattened end, and, on the other hand, the pressed length Lcenter of the centre of said connector needed to avoid that the superconducting wires are pressed together with the pressing of said centre.

7. The method according to claim 6,
wherein said method comprises the following step:
subjecting said connector and said first flattened end and second flattened end to a heat treatment to create superconductivity in the centre and to restore superconductivity in said first flattened end and second flattened end.

8. The method according to claim 7,
wherein said heat treatment comprises a first phase of heating in a range of 800° C. to 1000° C. during 20 minutes to 40 minutes and a second phase of heating in a range of 550° C. to 750° C. during 45 minutes to 75 minutes.

9. The method according to claim 6,
wherein flattening said first end of said at least one first superconducting wire and flattening said second end of said at least one second superconducting wire are done to a degree where the width to thickness ratio of said first end and of said second end range from 1.25 to 2.5, preferably from 1.50 to 2.0.

10. The method according to claim 6,
wherein said critical distance Lcr ranges from 0.6 mm to 5.0 mm.

11. The joint according to claim 1,
wherein said tubular metal connector comprises low carbon steel, and
wherein said tubular metal connector comprises titanium.

12. The joint according to claim 11,
wherein said tubular metal connector has a titanium barrier inside and a low carbon steel around said titanium barrier.
